(19) United States
(12) Patent Application Publication
(10) Pub. No.: US 2003/0147221 A1
(43) Pub. Date: Aug. 7, 2003

(54) Integral high current stamped metal circuit for printed circuit board bussed electrical center

(76) Inventors: Raymond J. Blasko, Boardman, OH (US); Mark W. Smith, Cortland, OH (US); Eduardo Nunez, El Paso, TX (US)

Correspondence Address: Thomas N Twomey Esq, DELPHI TECHNOLOGIES INC, M/C 480 410 202, P O Box 5052, Troy, MI, 48098-5052, US

(21) Appl. No.: 10/067,219

(22) Filed: Feb. 7, 2002

(51) Int. Cl. H05K 1/14

(52) U.S. Cl. 361/736

(57) ABSTRACT

A circuit assembly for vehicle power and electronic circuits in a printed circuit board bussed electrical center. The circuit assembly includes a stamped metal circuit with both power level terminals and solder tabs dispersed selectively along the longitudinal length of the stamped metal circuit. The solder tabs are press-fit and soldered to individual circuit board traces of a printed circuit board of the bussed electrical center. High current protective devices are directly connected to the stamped metal circuit.

### BACKGROUND OF THE INVENTION

The present invention relates to a printed circuit board bussed electrical center in a vehicle, and more particularly, to a high current stamped metal circuit that will accept a cable lead from a high current circuit and distribute the current throughout the printed circuit board bussed electrical center.

Commonly, automotive vehicles have had an electrical system for controlling a variety of vehicle functions comprising an electronics module in a protective housing connected by a harness to a separate bussed electrical center (BEC). The electronic module operates at signal level currents while the electrical center operates at higher power levels and is coupled to fuses, relays and devices capable of high current levels. Both components accept one or more harnesses from the vehicle with separate connectors.

BECs are used to simplify electrical system wiring by eliminating multi-branch wiring and consolidating fuses, relays, and other electrical circuit components in a single location. A BEC typically comprises a plastic case having a multitude of sockets formed therein for receiving the circuit components. The case contains bus bars or other conductive means for interconnecting and supplying power to the various circuit components. Electrical connectors are disposed on the BEC to receive mating connectors which terminate wire harnesses which extend throughout the vehicle to interconnect the circuitry of the BEC with the numerous electrical systems and devices elsewhere in the vehicle.

In a BEC, stamped metal circuits are a common method for bussing high current circuits, such as the battery power input circuit. With many electrical centers, the lower current circuits are bussed using a printed circuit board, while the high current circuits need the increased electrical current carrying capacity provided by stamped metal bussing. For this reason, printed circuit board BECs either include a stamped metal circuit for distributing the battery input circuit to devices (fuses and relays), or have increased the thickness of the circuit board copper layers to handle the higher electrical current. Both solutions are costly and limit the design flexibility of the electrical center.

The BEC designs that utilize a stamped metal circuit for the battery input circuit do not have a direct electrical connection of the stamped metal circuit to the printed circuit board. They are electrically connected only through a device such as a fuse or relay. In order to reach all of the devices that require battery power, the stamped metal circuit must often be the size of the entire electrical center. This large size for a stamped metal circuit is very costly. Furthermore, the stamped metal array needed to reach devices scattered throughout the electrical center occupies packaging space within the center that otherwise could be used for additional electrical content.

In U.S. Pat. No. 5,709,567, the disclosure of which is hereby incorporated by reference in its entirety, the invention includes a stamped electrical buss system including a stamped buss plate having a plurality of slots formed therein and a terminal having raised features that cause an electrical interconnection between the buss plate and the terminal. The invention discloses that the raised features are designed so that as the terminal is inserted into the stamped plate, the features displace the edges of the plate defining the slot and provide a gas-tight electrical interface.

In a different approach, U.S. Pat. No. 5,715,135, the disclosure of which is hereby incorporated by reference in its entirety, the invention includes a main stamped metal buss plate carried within a main insulation assembly as well as a plurality of other stamped metal circuit components which are press-fit into upper and lower halves of the main insulation assembly in a predetermined pattern. The stamped metal circuit component includes an ear portion for connection to a battery cable and high capacity male blades or tuning fork terminals for connection to maxi-fuses. The aforementioned designs limit design flexibility when electrical content is packaged within a BEC.

The BEC designs that do not employ a piece of stamped metal for the high current battery circuit use very thick printed circuit board copper layers in order to handle the electrical current load. This increases the cost of the circuit board. In one approach, U.S. Pat. No. 6,011,319, the disclosure of which is hereby incorporated by reference in its entirety, a single circuit board substrate is used for both power and signal level functions. One section of the board is dedicated to electronics including small terminals for signal input-output functions and one or more additional sections are dedicated to an array of larger terminals for connection to wiring harnesses, fuses and relays, or other pluggable devices. Ordinary printed circuit paths service both sections of the substrate but some supplementary power bus conductors interconnect selected large terminals to handle large currents in that region.

In U.S. Pat. No. 5,581,130, the disclosure of which is hereby incorporated by reference in its entirety, a plurality of interconnected modules are used to distribute power throughout the circuit board used for the control and/or power supply of electrical function devices of a vehicle. A coupling bar provides the connection of the modules to the electrical power supply.

In yet another approach, U.S. Pat. No. 6,062,916, the disclosure of which is hereby incorporated by reference in its entirety, the invention incorporates a terminal design that can be soldered into a printed circuit board to provide a compliant redundant electrical interface to the printed circuit board, and an electrical connection to an electronic/electrical device or wire harness circuit. High current busing is accomplished through the printed circuit board style terminals or using terminal carrier tabs located on each terminal, as a circuit bus. In such as case, two terminals or more are connected together by the terminal tabs extending therebetween. In this situation, no heavy copper traces are needed on the printed circuit board due to the design of the terminals. However, this design as well as the others previously referenced, can be improved upon resulting in smaller size, and a reduction in costs. Therefore, there is a need for an improved BEC that is reduced in size but maintains the current efficiency in design to adequately distribute the electrical load from high current circuits such as vehicle battery power input. The improved BEC can also benefit by resulting in lower production costs which can be carried over to the consumer.

### SUMMARY OF THE INVENTION

The present invention relates to a circuit assembly for vehicle power and electronic circuits in a printed circuit board bussed electrical center (BEC). The circuit assembly includes a stamped metal circuit capable of accepting a cable lead from a high current circuit. A plurality of solder tabs formed from the stamped metal circuit distribute electrical current throughout the printed circuit board of the BEC. The stamped metal circuit provides direct electrical connection to high current protection devices.

In one embodiment of the invention, the apparatus of the present invention includes a stamped metal circuit with a plurality of power level terminals dispersed along its longitudinal length at predetermined locations. A plurality of solder tabs formed from the stamped metal circuit are press-fit and soldered to a printed circuit board of the BEC to provide direct connections to individual circuit board traces that distribute electrical current throughout.

A working model of the presently disclosed invention has been constructed and tested by the inventors.

### BRIEF DESCRIPTION OF THE DRAWINGS

The various advantages of the present invention will become apparent to one skilled in the art by reading the following specification and subjoined claims and by referencing the following drawings in which:

FIG. 1 is a simplified perspective drawing of a printed circuit board bussed electrical center (prior art);

FIG. 2 is a perspective view of a stamped metal circuit in an embodiment of the invention;

FIG. 3 is a top view of a stamped metal circuit in an embodiment of the invention;

FIG. 4 is a side view of a stamped metal circuit in an embodiment of the invention; and

FIG. 5 is a top view of a printed circuit board in an embodiment of the invention.

### DETAILED DESCRIPTION OF THE INVENTION

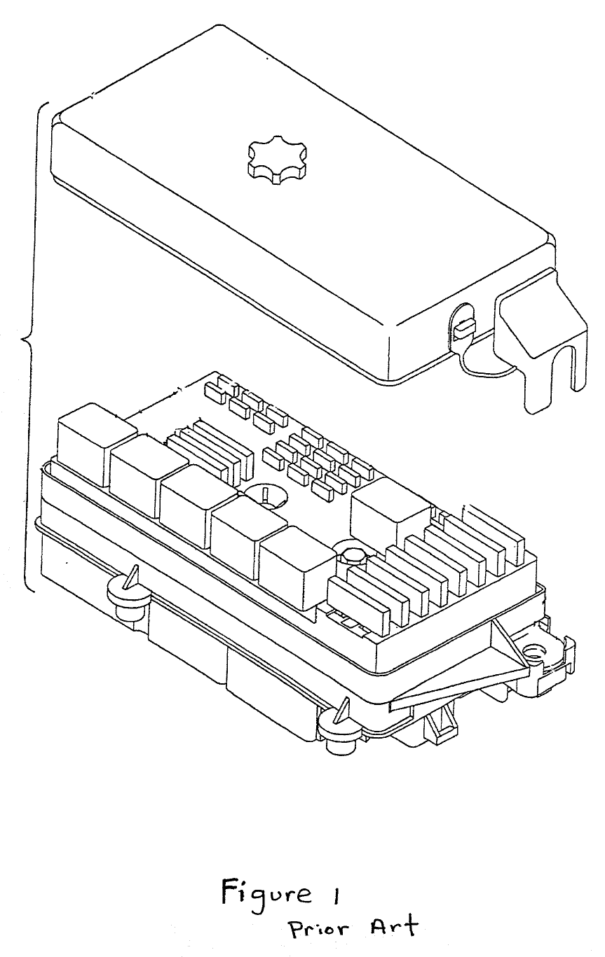

FIG. 1 depicts a prior art drawing of a printed circuit board bussed electrical center (BEC).

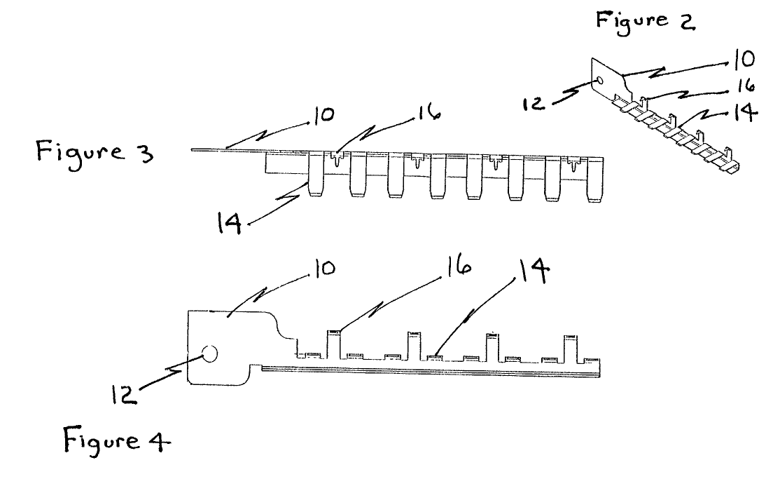

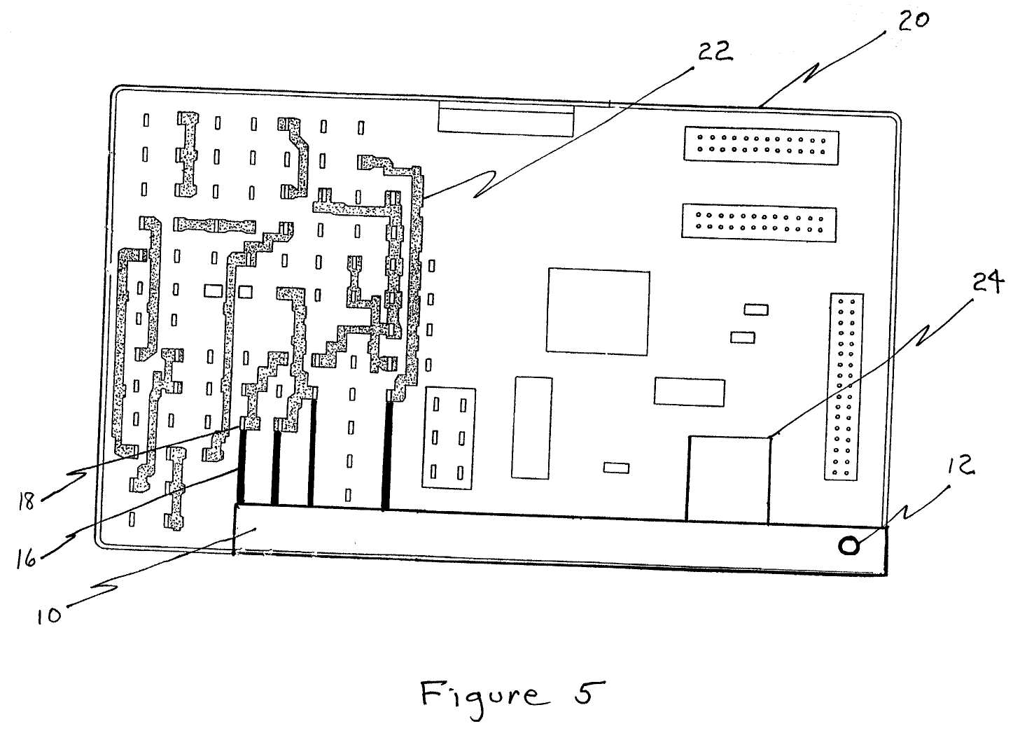

Referring to FIGS. 2, 3 and 4, three views of a stamped metal circuit 10 in an embodiment of the circuit assembly are displayed. The circuit assembly includes a stamped metal circuit 10 adapted to accept a cable lead 12 from a high current circuit (not shown) such as a vehicle battery input. A plurality of power level terminals 14 are formed from the stamped metal circuit 10 and are dispersed along its longitudinal length at predetermined locations(see FIGS. 2, 3 and 4). Electrical power is dispersed to other circuit assemblies in the BEC through the power level terminals 14.

A plurality of solder tabs 16 are formed from the stamped metal circuit 10 and are disposed along its longitudinal axis at a pre-selected angle. The pre-selected angle will allow the solder tabs 16 to be oriented in a corresponding plane to that of a printed circuit board (not shown) where they will be terminate in a solder connection. The solder tabs 16 are interspersed between the power level terminals 14 at predetermined locations dependent upon the power requirements of the BEC.

In FIG. 5, the solder tabs 16 are actively engaged with a plurality of plated through holes or slots 18 in the printed circuit board 20. The solder tabs 16 are press-fit and soldered at the plated through slots 18 to individual circuit board traces or paths 22 that distribute electrical current throughout the BEC. These soldered connections formed by the solder tabs 16 to the circuit board traces 22 at the plated through slots 18 are the direct electrical connections of the stamped metal circuit 10 to the low current protective devices (not shown) such as mini-fuses and relays. However, the stamped metal circuit 10 will be electrically connected directly to high current protective devices such as slow-blow high current fuses 24.

The press fit and soldered solder tabs 16 provide a secure, permanent, low resistance electrical connection between the stamped metal circuit 10 and the printed circuit board 20. The size of the stamped metal circuit 10 will only be as large as needed to adequately distribute the electrical load into the individual circuit board traces 22, and not sized to reach every associated device as with the prior art methods. This will result in a size reduction and a corresponding component cost reduction for the stamped metal circuit 10.

Since the input load is distributed or divided within the stamping before being connected to the individual circuit board traces 22, the copper thickness of the circuit board layers only has to be thick enough to handle the maximum distributed load. Prior methods were to size the printed circuit thickness to handle the entire input load. This reduction in copper thickness also reduces the cost of the printed circuit board 20.

Those skilled in the art can now appreciate from the foregoing description that the broad teachings of the present invention can be implemented in a variety of forms. Therefore, while this invention has been described in connection with particular examples thereof, the true scope of the invention should not be so limited since other modifications will become apparent to the skilled practitioner upon a study of the drawings, specification and following claims.

What is claimed is:

1. A circuit assembly for vehicle power and electronic circuits in a printed circuit board bussed electrical center, comprising:
a stamped metal circuit capable of accepting a cable lead from a high current circuit;
a plurality of power level terminals formed from said stamped metal circuit and dispersed along its longitudinal length at predetermined locations; and
a plurality of solder tabs formed from said stamped metal circuit, disposed at a preselected angle and interspersed between said power level terminals, dispersed at predetermined locations along the longitudinal length of said stamped metal circuit, and actively engaging a plurality of plated through slots in a printed circuit board of the printed circuit board bussed electrical center thus providing direct connections to individual circuit board traces that distribute electrical current throughout the printed circuit board bussed electrical center.

2. The circuit assembly according to claim 1, wherein said stamped metal circuit accepts a cable lead for a battery power input.

3. The circuit assembly according to claim 1, wherein said stamped metal circuit provides direct electrical connection to slow-blow high current fuses.

4. The circuit assembly according to claim 1, wherein said stamped metal circuit is sized to adequately distribute an electrical load into individual printed circuit board traces.

5. The circuit assembly according to claim 1, wherein said solder tabs are press fit and soldered into the plated through slots in the printed circuit board.

6. The circuit assembly according to claim 5, wherein said solder tabs provide a secure, permanent, low resistance electrical connection between said stamped metal circuit and said printed circuit board.

7. A circuit assembly for vehicle power and electronic circuits in a printed circuit board bussed electrical center comprising a stamped metal circuit capable of accepting a cable lead from a battery power input, a plurality of power level terminals formed from said stamped metal circuit and dispersed along its longitudinal length at predetermined locations, a plurality of solder tabs formed from said stamped metal circuit, disposed at a pre-selected angle and interspersed between said power level terminals and dispersed at predetermined locations along the longitudinal length of said stamped metal circuit, and actively engaging a plurality of plated through slots in a printed circuit board of the printed circuit board bussed electrical center thus providing direct connections to individual circuit board traces that distribute electrical current throughout the printed circuit board bussed electrical center.

8. The circuit assembly according to claim 7, wherein said solder tabs are press fit and soldered into the plated through slots in the printed circuit board.

9. The circuit assembly according to claim 7, wherein said stamped metal circuit provides direct electrical connection to slow-blow high current fuses.

10. A method for providing high current circuits for vehicle printed circuit board bussed electrical centers, said method comprising the steps of:
providing a stamped metal circuit capable of accepting a cable lead from a high current circuit including a cable lead for a battery power input;
providing a plurality of power level terminals formed from said stamped metal circuit and dispersed along its longitudinal length at predetermined locations; and
providing a plurality of solder tabs formed from said stamped metal circuit, disposed at a pre-selected angle and interspersed between said power level terminals, dispersed at predetermined locations along the longitudinal length of said stamped metal circuit, and actively engaging a plurality of plated through slots in a printed circuit board of the printed circuit board bussed electrical center thus providing direct connections to individual circuit board traces that distribute electrical current throughout the printed circuit board bussed electrical center.

11. The method according to claim 10, wherein said method includes the further step of providing direct electrical connection to slow-blow high current fuses.

12. The method according to claim 10, wherein said method includes the further step of press fitting and soldering said solder tabs into the plated through slots in the printed circuit board.

13. The method according to claim 10, wherein said method includes the further step of sizing said stamped metal circuit to adequately distribute an electrical load into individual printed circuit board traces.
